(19) United States
(12) Patent Application Publication
(10) Pub. No.: US 2018/0051136 A1
(43) Pub. Date: Feb. 22, 2018

(54) PHOTOSENSITIVE RESIN COMPOSITION AND ELECTRONIC COMPONENT

(71) Applicant: TORAY INDUSTRIES, INC., Tokyo (JP)

(72) Inventors: Yutaro KOYAMA, Otsu-shi (JP); Ryoji OKUDA, Otsu-shi (JP); Yuki MASUDA, Otsu-shi (JP); Tomohiro KITAMURA, Otsu-shi (JP); Yu SHOJI, Otsu-shi (JP)

(73) Assignee: TORAY INDUSTRIES, INC., Tokyo (JP)

(21) Appl. No.: 15/555,173

(22) PCT Filed: Feb. 29, 2016
(86) PCT No.: PCT/JP2016/056061

§ 371 Date: Sep. 1, 2017

(30) Foreign Application Priority Data
Mar. 6, 2015 (JP) 2015-044431

(51) Int. Cl. C08G 73/10; G03F 7/039; G03F 7/004; G03F 7/031; G03F 7/16; G03F 7/20; G03F 7/32; G03F 7/40; G03F 7/022; H01L 23/00

(52) U.S. Cl. CPC C08G 73/1039; H01L 2224/0362; G03F 7/0045; G03F 7/031; G03F 7/162; G03F 7/168; G03F 7/2004; G03F 7/322; G03F 7/40; G03F 7/022; H01L 24/03; H01L 24/05; H01L 2224/02331; H01L 2224/024; H01L 2224/0401; H01L 2224/05008; H01L 2924/07025; H01L 2924/3511; G03F 7/039

(57) ABSTRACT

Provided is a resin which has high elongation, low stress, high sensitivity and high film retention ratio if used in a photosensitive resin composition. A photosensitive resin composition that contains a resin which has a structure represented by general formula (1) and/or general formula (2), and which is characterized in that (a) 10-80% by mole of an organic group having an alicyclic structure and 4-40 carbon atoms is contained as the R¹ moiety of general formulae (1) and (2), and (b) 10-80% by mole of an organic group having a polyether structure with 20-100 carbon atoms is contained as the R² moiety of general formulae (1) and (2). (In general formulae (1) and (2), R¹ represents a tetravalent organic group having a monocyclic or condensed polycyclic alicyclic structure and 4-40 carbon atoms; R² represents a divalent organic group having a polyether structure with 20-100 carbon atoms; R³ represents a hydrogen atom or an organic group having 1-20 carbon atoms; each of n1 and n2 represents a number within the range of 10-100,000; and p and q represents integers satisfying 0≦p+q≦6.)

### TECHNICAL FIELD

The present invention relates to a resin which contains a specific structure. More specifically, the present invention relates to a resin suitable for use in a surface protective film or an interlayer dielectric film for a semiconductor device and an inductor device, a dielectric layer and a spacer layer for an organic electroluminescent element, and the like, and to a photosensitive resin composition containing the resin.

### BACKGROUND ART

Polyimide resins are highly heat-resistant and highly electrically insulative and have excellent mechanical characteristics, and thus are widely used in surface protective films and interlayer dielectric films for semiconductor devices and inductor devices, dielectric layers and spacer layers for organic electroluminescent elements, and the like.

In the case where a polyimide is used as a surface protective film or an interlayer dielectric film, one way to form a through hole or the like is etching which uses a positive photoresist. However, this method has a problem in that the process involves applying and releasing the photoresist and thus is complicated. In view of this, a study has been done on a photosensitive heat-resistant material in an attempt to streamline the operation process.

In recent years, semiconductor devices have had a more finely processed pattern, a miniaturized and densified package, a higher speed, and a larger capacity, because of which polyimides are not only used as buffer coats but also in greater demand in rewiring applications in which polyimides are used in multiple layers as interlayer dielectric films between metal wiring layers. Also in electronic components such as inductor devices, there is a greater demand for interlayer dielectric films adaptable to multilayer wiring, such as in common mode filter applications in which a coil is formed by layering metal wiring layers and polyimide layers one on another (for example, Patent Literature 1). In these applications, there has been a requirement for a photosensitive resin composition that has characteristics such as a high degree of elongation that can withstand the torsion and expansion of a substrate and impact, a stressfulness low enough to reduce substrate warpage during layer-forming, and a high sensitivity and a high residual film rate that allow the processing of a film having a larger thickness.

In order to satisfy such requirements, there has been proposed a photosensitive resin composition which achieves a high sensitivity by using a highly transparent polyimide containing a tetracarboxylic anhydride having an alicyclic structure (for example, refer to Patent Literature 2 to 4).

For low stressfulness, a polyamic acid and a polyimide resin that use a flexible aliphatic monomer have been proposed. (For example, refer to Patent Literature 5 and 6).

### CITATION LIST

### Patent Literature

### Patent Literature 1: JP 2014-229739 A

### Patent Literature 2: WO 00/73853

### Patent Literature 3: WO 13/024849

### Patent Literature 4: JP 2007-183388 A

### Patent Literature 5: WO 11/059089

### Patent Literature 6: JP 2014-065776 A

### SUMMARY OF INVENTION

### Technical Problem

However, the known polyimide resins containing a tetracarboxylic anhydride having an alicyclic structure are too soluble in an alkaline developer, resulting in having a low residual film rate after development, and thus cannot easily form a thick film structure. In addition, the polyimide resins lack flexibility, hence having a low degree of elongation, and cause a large warpage to a substrate.

Although conventional polyamic acids and polyimide resins using a flexible aliphatic monomer have a low stressfulness, they need to have a large amount of flexible aliphatic groups introduced into their molecule chains in order to have a high degree of elongation, and that large amount introduced will involve a high hydrophilicity, thereby causing tackiness and residues to be found after development.

In consideration of the problems of the above-described known techniques, it is an object of the present invention to provide a resin that has a high degree of elongation, a low stressfulness, a high sensitivity, and a high residual film rate when used in a photosensitive resin composition.

### Solution to Problem

In order to achieve the above object, the resin composition according to the present invention includes the following constitution: in other words, a photosensitive resin composition including an alkali-soluble resin selected from an alkali-soluble polyimide having a structural unit represented by the general formula (1), a polyimide precursor represented by the general formula (2), or a copolymer thereof.

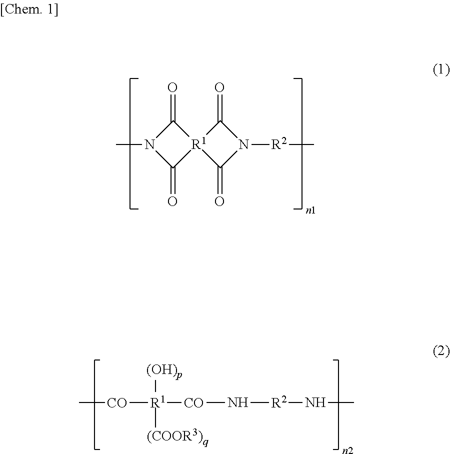

wherein, in the general formulae (1) and (2), R¹ represents a C₄-C₄₀ tetravalent organic group having an alicyclic structure of a monocyclic or fused polycyclic type; R² represents a C₂₀-C₁₀₀ bivalent organic group having a polyether structure; R³ represents hydrogen or a C₁-C₂₀ organic group; n1 and n2 are each in the range of 10 to 100,000; and p and q represent an integer satisfying 0≦p+q≦6.

Another aspect according to the present invention is an electronic component using the resin composition according to the present invention.

### Effects of Invention

The present invention provides a photosensitive resin composition capable of affording an excellent cured film that has a high degree of elongation, a low stressfulness, a high sensitivity, and a high residual film rate.

### BRIEF DESCRIPTION OF DRAWINGS

FIG. 1 is a cross-sectional view of a pad portion of a semiconductor device showing an embodiment according to the present invention.

FIG. 2 is a cross-sectional view of a semiconductor device showing an embodiment according to the present invention in a production process.

FIG. 3 is a cross-sectional view of a coil part of an inductor device showing an embodiment according to the present invention.

### DESCRIPTION OF EMBODIMENTS

The resin according to the present invention is a photosensitive resin composition including an alkali-soluble resin selected from an alkali-soluble polyimide having a structural unit represented by the general formula (1), a polyimide precursor represented by the general formula (2), and a copolymer thereof.

In the general formulae (1) and (2), R¹ represents a C₄-C₄₀ tetravalent organic group having an alicyclic structure of a monocyclic or fused polycyclic type. R² represents a C₂₀-C₁₀₀ bivalent organic group having a polyether structure. R³ represents hydrogen or a C₁-C₂₀ organic group. n1 and n2 are each in the range of 10 to 100,000, and p and q represent an integer satisfying 0≦p+q≦6.

Because the resin has a monoalicyclic or fused polyalicyclic structure, resulting in having a lower absorbancy, the resin can afford a photosensitive resin composition having a high sensitivity even if it is a thick film. In addition, because of having a linear and rigid structure, this photosensitive resin composition can afford a cured film having a high degree of elongation when applied to a substrate and heat-cured. Furthermore, because of having a polyether structure that has a high flexibility, the photosensitive resin composition can afford a cured film having a low stressfulness in addition to a high degree of elongation.

R¹ in the general formulae (1) and (2) preferably contains one or more organic groups selected from the following general formulae (3) to (6):

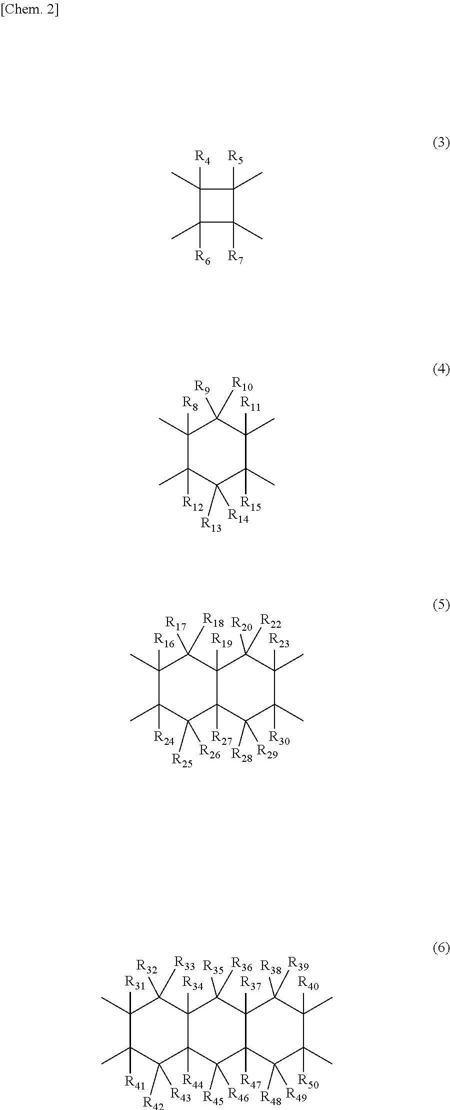

wherein, in the general formulae (3) to (6), R⁴ to R⁵⁰ each independently represent a hydrogen atom, a halogen atom, or a C₁-C₃ monovalent organic group; and a hydrogen atom contained in the C₁-C₃ monovalent organic group may be substituted by a halogen atom.

R¹ in the general formulae (1) and (2) is an organic group derived from an acid dianhydride that is used as a raw material of a resin.

Specific examples of acid dianhydrides used in the present invention that contain a C₄-C₄₀ tetravalent organic group having an alicyclic structure of a monocyclic or fused polycyclic type can include compounds such as 1,2,3,4-cyclobutanetetracarboxylic dianhydride, 1,2-dimethyl-1,2,3,4-cyclobutanetetracarboxylic dianhydride, 1,2,3,4-tetramethyl-1,2,3,4-cyclobutanetetracarboxylic dianhydride, and 1,2,4,5-cyclohexanetetracarboxylic dianhydride.

These structures are preferable in that they can produce a higher degree of elongation when at 10 mol % or more and afford a suitable rate of dissolution into a developer when at 80 mol % or less, relative to R¹ in the structures represented by the general formulae (1) and (2) as 100 mol %, and are more preferably at 30 mol % to 60 mol %.

In addition, R² in the general formulae (1) and (2) preferably contains an organic group having a polyether structure represented by the following general formula (7):

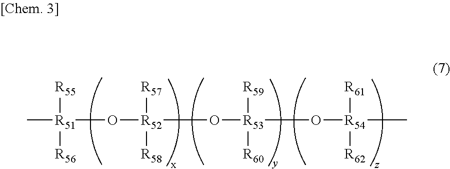

wherein, in the general formula (7), R⁵¹ to R⁵⁴ represent a C₁-C₁₀ tetravalent organic group, and R⁵⁵ to R⁶² represent a hydrogen atom or a C₁-C₁₀ monovalent organic group.

R² in the general formulae (1) and (2) is an organic group derived from a diamine that is used as a raw material of a resin.

Specific examples of diamines used in the present invention that contain an organic group having a polyether structure include aliphatic diamines such as JEFFAMINE HK-511, ED-600, ED-900, ED-2003, EDR-148, EDR-176, D-200, D-400, D-2000, D-4000, ELASTAMINE RP-409, RP-2009, RT-1000, HT-1100, HE-1000, and HT-1700 (those listed above are the names of products available from HUNTSMAN Corporation). Having a polyether structure is preferable because it imparts flexibility and thus enhances degree of elongation and because it reduces elastic modulus and thus suppresses the warpage of a wafer. These characteristics are effective for multiple layers and thick films. A polyether structure represented by the general formula (7) is preferable in that it can achieve a low stressfulness by imparting flexibility to the resin when at 10 mol % or more and afford a suitable rate of dissolution into a developer when at 80 mol % or less, relative to R² in the structures represented by the general formulae (1) and (2) as 100 mol %, and is more preferably at 20 mol % to 50 mol %.

In addition, further containing a fluorine-atom-containing organic group as R¹ in the general formulae (1) and (2) imparts water repellency to the resin and thus allows the resin to suppress permeation through the film surface during alkaline development, so that the resin can afford a resin film having a high residual film rate, in which resin film there is no tackiness on the unexposed parts nor development residue on the processed pattern. These characteristics are effective in processing thick films. The fluorine-atom-containing organic group is preferable in that it can produce the effect of preventing permeation at an interface when at 20 mol % or more and afford a suitable rate of dissolution into a developer when at 90 mol % or less, relative to the total amount of R¹ as 100 mol %, and is more preferably at 40 mol % to 60 mol %.

Specific examples of compounds having a fluorine atom include aromatic acid dianhydrides such as 2,2-bis(3,4-dicarboxyphenyl)hexafluoropropane dianhydride, compounds obtained by substituting an aromatic ring of the dianhydride with an alkyl group or a halogen atom, acid dianhydrides having an amide group, and the like. The resin having a structure represented by the general formulae (1) and (2) is preferably a resin that contains a structure derived from any of these compounds.

With the use of the above-described acid dianhydride having a C₄-C₄₀ alicyclic structure, diamine having a C₂₀-C₁₀₀ polyether structure, and compound containing a fluorine atom in the above-described ranges, it is possible to obtain a highly photosensitive resin composition having a high residual film rate that has a high degree of elongation and a low stressfulness and yet leaves no tackiness nor development residue after development.

These characteristics are useful particularly in rewiring applications for semiconductor devices and noise filter applications for inductor devices, in both of which devices the resin composition is used in multiple layers as interlayer dielectric films between metal wiring layers.

The photosensitive resin composition according to the present invention may also have a structure derived from another acid dianhydride and diamine in addition to the above-described acid dianhydride and diamine to the extent that the above-described characteristics are not impaired.

Specific examples of acid dianhydrides include: aromatic tetracarboxylic dianhydrides such as pyromellitic dianhydride, 3,3′,4,4′-biphenyl tetracarboxylic dianhydride, 2,3,3′,4′-biphenyl tetracarboxylic dianhydride, 2,2′,3,3′-biphenyl tetracarboxylic dianhydride, 3,3′,4,4′-benzophenone tetracarboxylic dianhydride, 2,2′,3,3′-benzophenone tetracarboxylic dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, 1,2,5,6-naphthalenetetracarboxylic dianhydride, 2,3,6,7-naphthalenetetracarboxylic dianhydride, 2,3,5,6-pyridinetetracarboxylic dianhydride, 3,4,9,10-perylenetetracarboxylic dianhydride, bis(3,4-dicarboxyphenyl)sulfone dianhydride, 3,3′,4,4′-diphenyl ether tetracarboxylic dianhydride, or compounds obtained by substituting a hydrogen atom of these compounds with an alkyl group or a halogen atom; alicyclic and semi-alicyclic tetracarboxylic dianhydrides such as 5-(2,5-dioxotetrahydrofuryl)-3-methyl-3-cyclohexene-1,2-dicarboxylic dianhydride, 2,3,5-tricarboxy-2-cyclopentaneacetic dianhydride, bicyclo[2.2.2]octo-7-ene-2,3,5,6-tetracarboxylic dianhydride, 2,3,4,5-tetrahydrofurantetracarboxylic dianhydride, 3,5,6-tricarboxy-2-norbornaneacetic dianhydride, 3,4-dicarboxy-1,2,3,4-tetrahydro-1-naphthalenesuccinic dianhydride, or compounds obtained by substituting a hydrogen atom of these compounds with an alkyl group or a halogen atom; acid dianhydrides having an amide group; and the like. These together with an acid dianhydride that has a C₄-C₄₀ alicyclic structure may be used in combination of two or more kinds thereof.

Specific examples of diamines include hydroxyl-containing diamines such as bis(3-amino-4-hydroxyphenyl) hexafluoropropane, bis(3-amino-4-hydroxyphenyl) sulfone, bis(3-amino-4-hydroxyphenyl) propane, bis(3-amino-4-hydroxyphenyl) methylene, bis(3-amino-4-hydroxyphenyl) ether, bis(3-amino-4-hydroxy) biphenyl, and bis(3-amino-4-hydroxyphenyl) fluorene; sulfonic acid-containing diamines such as 3-sulfonic acid-4,4′-diaminodiphenyl ether; thiol-containing diamines such as dimercapto-phenylenediamine; and aromatic diamines such as 3,4′-diaminodiphenyl ether, 4,4′-diaminodiphenyl ether, 3,4′-diaminodiphenyl methane, 4,4′-diaminodiphenyl methane, 3,4′-diaminodiphenyl sulfone, 4,4′-diaminodiphenyl sulfone, 3,4′-diaminodiphenyl sulfide, 4,4′-diaminodiphenyl sulfide, 1,4-bis(4-aminophenoxy) benzene, benzine, m-phenylenediamine, p-phenylenediamine, 1,5-naphthalenediamine, 2,6-naphthalenediamine, bis(4-aminophenoxyphenyl) sulfone, bis(3-aminophenoxyphenyl) sulfone, bis(4-aminophenoxy) biphenyl, bis{4-(4-aminophenoxy)phenyl} ether, 1,4-bis(4-aminophenoxy) benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, and 2,2′-bis(trifluoromethyl)-4,4′-diaminobiphenyl; and compounds obtained by partially substituting hydrogen atoms of aromatic rings of these diamines with C₁-C₁₀ alkyl groups, fluoroalkyl groups, halogen atoms, or the like; alicyclic diamines such as cyclohexyldiamine and methylenebiscyclohexylamine; and the like. These diamines may be used without changes or may be used as corresponding diisocyanate compounds or trimethylsilylated diamines. Two or more of these diamine components may be used in combination.

Preferred among those listed above are 3,4′-diaminodiphenyl ether, 4,4′-diaminodiphenyl ether, 3,4′-diaminodiphenyl sulfone, 4,4′-diaminodiphenyl sulfone, 3,4′-diaminodiphenyl sulfide, 4,4′-diaminodiphenyl sulfide, bis(4-aminophenoxyphenyl) sulfone, bis(3-aminophenoxyphenyl) sulfone, bis(4-aminophenoxy) biphenyl, bis {4-(4-aminophenoxy)phenyl} ether, 1,4-bis(4-aminophenoxy) benzene, 1,3-bis(4-aminophenoxy) benzene, 2,2-bis[4-(4-aminophenoxy)phenyl] hexafluoropropane, 2,2-bis[4-(4-aminophenoxy)phenyl] propane, 2,2-bis(3-amino-4-hydroxyphenyl) hexafluoropropane, and compounds obtained by substituting aromatic rings of those listed above with alkyl groups or halogen atoms, and diamines having an amide group. These are used singly or in combination of two or more kinds thereof.

Furthermore, these components may be copolymerized with an aliphatic group having a siloxane structure to the extent that the heat resistance is not reduced, thereby making it possible to improve the adhesion to a substrate. Specific examples include those copolymerized with a 1 to 15 mol % diamine component such as bis(3-aminopropyl)tetramethyl disiloxane or bis(p-amino-phenyl)octamethyl pentasiloxane.

For the use that requires heat resistance, it is preferable to use an aromatic diamine in an amount of 50 mol % or more with respect to the total amount of diamines.

Furthermore, the resin having a structure represented by the general formulae (1) and (2) preferably has a phenolic hydroxyl component. It is preferable that, in the general formulae (1) and (2), at least one of R¹ and R² be an organic group that has a phenolic hydroxyl group. Phenolic hydroxyl groups provide adequate solubility in alkaline developers and interact with a photosensitizer to reduce the solubility of unexposed portions. Therefore, it is possible to improve the residual film rate and increase sensitivity. In addition, since the phenolic hydroxyl groups also contribute to the reaction with crosslinking agents, the resin containing a phenolic hydroxyl component is preferable also in terms of high mechanical characteristics and high chemical resistance.

Specific examples of a compound that has a phenolic hydroxyl group include aromatic acid dianhydrides such as 2,2-bis(3,4-dicarboxyphenyl)hexafluoropropane dianhydride, compounds obtained by substituting aromatic rings of the dianhydride with alkyl groups or halogen atoms, and acid dianhydrides having an amide group, hydroxyl-containing diamines such as bis(3-amino-4-hydroxyphenyl) hexafluoropropane, bis(3-amino-4-hydroxyphenyl) sulfone, bis(3-amino-4-hydroxyphenyl) propane, bis(3-amino-4-hydroxyphenyl) methylene, bis(3-amino-4-hydroxyphenyl) ether, bis(3-amino-4-hydroxy) biphenyl, and bis(3-amino-4-hydroxyphenyl) fluorene, and compounds obtained by partially substituting hydrogen atoms of aromatic rings of these diamines with C₁-C₁₀ alkyl groups, fluoroalkyl groups, halogen atoms, or the like. The resin having a structure represented by the general formulae (1) and (2) is preferably a resin that contains a structure derived from any of these compounds.

In the general formulae (1) and (2), n1 and n2 represent a degree of polymerization. When the molecular weight per unit in the general formulae (1) and (2) is M, the number-average molecular weight of an alkali-soluble resin is Mn, the degree of polymerization n is determined in accordance with the equation n=Mn/M. The number-average molecular weight of an alkali-soluble resin can be determined by GPC (gel permeation chromatography) as described in Examples.

The weight-average molecular weight of the resin having a structure represented by the general formulae (1) and (2) is preferably 3,000 to 80,000, more preferably 8,000 to 50,000, which are polystyrene-equivalent molecular weights obtained by gel permeation chromatography. Provided that the weight-average molecular weight is within this range, a thick film can be readily formed.

A terminal of the resin having a structure represented by the general formulae (1) or (2) may be blocked with a terminal blocking agent such as a monoamine, an acid anhydride, an acid chloride, and a monocarboxylic acid. By blocking the terminal of the resin with a terminal blocking agent that has a hydroxyl group, a carboxyl group, a sulfonic group, a thiol group, a vinyl group, an ethynyl group, or an allyl group, it is possible to readily control the rate of dissolution of the resin in the alkaline aqueous solution within a preferred range. The terminal blocking agent is used in an amount of preferably 0.1 to 60 mol %, more preferably 5 to 50 mol %, with respect to the total amount of amine components of the resin.

Specific examples of terminal blocking agents include: monoamines such as 3-aminophenylacetylene, 4-aminophenylacetylene, and 3,5-diethynylaniline; monocarboxylic acids such as 3-ethynylbenzoic acid, 4-ethynylbenzoic acid, 3,4-diethynylbenzoic acid, and 3,5-diethynylbenzoic acid; acid anhydrides such as maleic anhydride and 5-norbornene-2,3-dicarboxylic anhydride; compounds resulting from the aforementioned monocarboxylic acids whose carboxyl group has been made into an acid chloride, and compounds resulting from dicarboxylic acids, such as maleic acid, one of whose carboxyl groups has been made into an acid chloride; terminal blocking agents having an unsaturated bond, such as active ester compounds obtained by the reaction of a monoacid chloride compound with n-hydroxy-5-norbornene-2,3-dicarboxy imide; monoamines such as 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxy pyrimidine, 2-aminophenol, 3-aminophenol, 4-aminophenol, 2-aminothio phenol, 3-aminothio phenol, and 4-aminothio phenol; acid anhydrides such as phthalic anhydride, cyclohexanedicarboxylic anhydride, and 3-hydroxyphthalic anhydride; monocarboxylic acids such as 3-carboxyphenol, 4-carboxyphenol, 3-carboxythiophenol, 4-carboxythiophenol, 1-hydroxy-7-carboxynaphthalene, 1-hydroxy-6-carboxynaphthalene, 1-hydroxy-5-carboxynaphthalene, 1-mercapto-7-carboxynaphthalene, 1-mercapto-6-carboxynaphthalene, 1-mercapto-5-carboxynaphthalene, 3-carboxybenzenesulfonic acid, 4-carboxybenzenesulfonic acid, and monoacid chloride compounds resulting from these monocarboxylic acids whose carboxyl group has been made into an acid chloride; monoacid chloride compounds resulting from dicarboxylic acids, such as terephthalic acid, phthalic acid, cyclohexanedicarboxylic acid, 1,5-dicarboxynaphthalene, 1,6-dicarboxynaphthalene, 1,7-dicarboxynaphthalene, and 2,6-dicarboxynaphthalene, only one of whose carboxyl groups has been made into an acid chloride; and terminal blocking agents having no unsaturated bond, such as active ester compounds obtained by the reaction of a monoacid chloride compound with n-hydroxybenzotriazole. Alternatively, when a hydrogen bond of these terminal blocking agents having no unsaturated bond is substituted with a vinyl group, the agents can be used as terminal blocking agents having an unsaturated bond.

The resin having a structure represented by the general formulae (1) and (2) may be produced in accordance with a known method of producing a polyimide or a polyimide precursor. Examples of the method include (I) a method by which a tetracarboxylic dianhydride having an R¹ group, a diamine compound having an R² group, and a monoamino compound which is a terminal blocking agent are reacted with each other at low temperature; (II) a method by which a diester is obtained from a tetracarboxylic dianhydride having an R¹ group and an alcohol and the diester is then reacted with a diamine compound having an R² group and a monoamino compound which is a terminal blocking agent in the presence of a condensation agent; and (III) a method by which a diester is obtained from a tetracarboxylic dianhydride having an R¹ group and an alcohol, remaining two carboxyl groups are then converted into acid chlorides, and the resultant is reacted with a diamine compound having an R² group and a monoamino compound which is a terminal blocking agent. The resin polymerized in the manner described above is preferably put in a large amount of water, a methanol/water mixture, or the like so as to precipitate, and filtered out, dried, and isolated. This precipitation operation removes unreacted monomers and oligomer components such as dimers and trimers to improve the characteristics of a heat-cured film. Furthermore, a cyclized polyimide obtained by imidizing a polyimide precursor may be synthesized by a known method of imidizing the polyimide precursor obtained above.

The following describes an example of a method of producing a polyimide precursor, which is a preferred example of the method (I). First, a diamine compound having an R² group is dissolved in a polymerization solvent. A tetracarboxylic dianhydride having an R¹ group in substantially the same molar quantity as the diamine compound is gradually added to the solution. The solution is stirred with the use of a mechanical stirrer at −20 to 100° C., preferably 10 to 50° C. for 0.5 to 100 hours, more preferably 2 to 24 hours. In the case where a terminal blocking agent is used, the terminal blocking agent may be gradually added after the tetracarboxylic dianhydride is added and stirred at a desired temperature for a desired period of time, or may be added at one time and reacted.

The polymerization solvent is not limited to a particular kind, provided that the polymerization solvent dissolves tetracarboxylic dianhydrides and diamines which are raw monomers. Examples of the polymerization solvent include amides such as N,N-dimethylformamide, N,N-dimethylacetamide, and N-methyl-2-pyrrolidone; cyclic esters such as γ-butyrolactone, γ-valerolactone, δ-valerolactone, γ-caprolactone, ε-caprolactone, and α-methyl-γ-butyrolactone; carbonates such as ethylene carbonate and propylene carbonate; glycols such as triethylene glycol; phenols such as m-cresol and p-cresol; acetophenone; 1,3-dimethyl-2-imidazolidinone; sulfolane; and dimethyl sulfoxide.

The polymerization solvent is preferable at 100 parts by mass or more relative to 100 parts by mass of the resulting resin because the reaction can be carried out without precipitation of a raw material or a resin, preferable at 1900 parts by mass or less because the reaction progresses rapidly, and more preferable at 150 to 950 parts by mass.

The photosensitive resin composition according to the present invention contains a photosensitizer, thereby having positive-working or negative-working photosensitivity.

The following describes a photosensitive resin composition having a positive-working photosensitivity according to the present invention, but, the scope of the present invention is not limited to such a photosensitive resin composition. Also in regard to a photosensitive resin composition having a negative sensitivity in which the portion exposed to light is reacted by development, when a polyimide having a poor transparency is used, the photoreactive efficiency of the photosensitizer in the exposed portion decreases and thus the residual film rate decreases, resulting in difficulty of obtaining a thick film structure. The use of the resin according to the present invention can afford a photosensitive resin composition having a high sensitivity in the form of a negative-working composition as well as a positive-working composition because the resin has a high transparency.

The photosensitive resin composition according to the present invention contains a photo acid generator, thereby having positive-working photosensitivity. In other words, the photo acid generator has the characteristics in that it generates an acid upon irradiation with light, resulting in increasing the solubility of the irradiated portion into an alkaline aqueous solution. Examples of photo acid generators include a quinonediazide compound, a sulfonium salt, a phosphonium salt, a diazonium salt, and an iodonium salt.

Examples of the quinonediazide compounds include compounds in which a quinonediazide sulfonic acid is bound to a polyhydroxy compound by an ester bond, compounds in which a quinonediazide sulfonic acid is bound to a polyamino compound by a sulfonamide bond, and compounds in which a quinonediazide sulfonic acid is bound to a polyhydroxypolyamino compound by an ester bond and/or a sulfonamide bond. Although not all the functional groups of these polyhydroxy compounds and polyamino compounds have to be substituted with quinonediazides, it is preferable that 50 mol % or more of all the functional groups be substituted with quinonediazides. If 50 mol % or more of the functional groups are substituted with quinonediazides, the solubility in an alkaline developer does not become too high, the contrast to the unexposed portion can be achieved, and a desired pattern can be obtained. The use of such a quinonediazide compound makes it possible to obtain a positive-working photosensitive resin composition which is sensitive to i-line (365 nm), h-line (405 nm), and g-line (436 nm) from a mercury lamp which are typical ultraviolet rays. These compounds may be used individually or a mixture of two or more of them may be used. Furthermore, the use of two photo acid generators makes it possible to increase the ratio of the dissolution rate of the exposed portion to that of the unexposed portion and, as a result, possible to obtain a highly photosensitive resin composition.

Examples of the polyhydroxy compounds include, but are not limited to, Bis-Z, BisP-EZ, TekP-4HBPA, TrisP-HAP, TrisP-PA, TrisP-SA, TrisOCR-PA, BisOCHP-Z, BisP-MZ, BisP-PZ, BisP-IPZ, BisOCP-IPZ, BisP-CP, BisRS-2P, BisRS-3P, BisP-OCHP, methylene tris-FR-CR, BisRS-26X, DML-MBPC, DML-MBOC, DML-OCHP, DML-PCHP, DML-PC, DML-PTBP, DML-34X, DML-EP, DML-POP, dimethylol-BisOC-P, DML-PFP, DML-PSBP, DML-MTrisPC, TriML-P, TriML-35XL, TML-BP, TML-HQ, TML-pp-BPF, TML-BPA, TMOM-BP, HML-TPPHBA, HML-TPHAP (those listed above are the names of products available from Honshu Chemical Industry Co., Ltd.), BIR-OC, BIP-PC, BIR-PC, BIR-PTBP, BIR-PCHP, BIP-BIOC-F, 4PC, BIR-BIPC-F, TEP-BIP-A, 46DMOC, 46DMOEP, TM-BIP-A (those listed above are the names of products available from Asahi Organic Chemicals Industry Co., Ltd.), 2,6-dimethoxymethyl-4-t-butyl phenol, 2,6-dimethoxymethyl-p-cresol, 2,6-diacetoxymethyl-p-cresol, naphthol, tetrahydroxy benzophenone, methyl gallate ester, bisphenol A, bisphenol E, methylene bisphenol, and BisP-AP (the name of a product available from Honshu Chemical Industry Co., Ltd.).

Examples of the polyamino compounds include, but are not limited to, 1,4-phenylenediamine, 1,3-phenylenediamine, 4,4′-diaminodiphenyl ether, 4,4′-diaminodiphenyl methane, 4,4′-diaminodiphenyl sulfone, and 4,4′-diaminodiphenyl sulfide.

Examples of the polyhydroxy polyamino compounds include, but are not limited to, 2,2-bis(3-amino-4-hydroxyphenyl) hexafluoro propane and 3,3′-dihydroxy benzidine.

In the present invention, a preferred form of a quinonediazide may either be a 5-naphthoquinonediazide sulfonyl group or a 4-naphthoquinonediazide sulfonyl group. A 4-naphthoquinonediazide sulfonyl ester compound has an absorbency in the i-line region of the mercury lamp and thus is suitable for i-line exposure. A 5-naphthoquinonediazide sulfonyl ester compound has an absorbency that reaches the g-line region of the mercury lamp and thus is suitable for g-line exposure. In the present invention, it is preferable to select a 4-naphthoquinonediazide sulfonyl ester compound or a 5-naphthoquinonediazide sulfonyl ester compound depending on the wavelength of the light for exposure. Furthermore, a naphthoquinonediazide sulfonyl ester compound that has both a 4-naphthoquinonediazide sulfonyl group and a 5-naphthoquinonediazide sulfonyl group per molecule may be obtained, or a mixture of a 4-naphthoquinonediazide sulfonyl ester compound and a 5-naphthoquinonediazide sulfonyl ester compound may be used.

The molecular weight of a quinonediazide compound according to the present invention is preferably 300 to 3000. In the case where the molecular weight of the quinonediazide compound is more than 3000, the quinonediazide compound is not pyrolyzed sufficiently during the heat treatment performed afterwards, and thus there may be a problem in that the heat resistance of the resulting film decreases, mechanical characteristics of the resulting film decrease, or the adhesiveness of the resulting film decreases.

The quinonediazide compound for use in the present invention is synthesized from a specific phenol compound by the following method. An example of the method is a method by which a 5-naphthoquinonediazide sulfonyl chloride and a phenolic compound are reacted in the presence of triethylamine. The phenol compound is synthesized by, for example, a method by which an α-(hydroxyphenyl) styrene derivative is reacted with a polyhydric phenolic compound in the presence of an acid catalyst.

The photo acid generator for use in the present invention is preferably a sulfonium salt, a phosphonium salt, or a diazonium salt which is a photo acid generator that moderately stabilizes the acid component generated by exposure to light. Since a resin composition obtained from the photosensitive resin composition of the present invention is used as a permanent film, the remaining phosphorus or the like is not preferred for environmental reasons. Further, the color tone of the film needs to be taken into consideration. Therefore, a sulfonium salt is preferred among those listed above. In particular, preferred is a triarylsulfonium salt, which can remarkably enhance the standing stability after exposure.

The amount of each photo acid generator for use in the present invention is preferably 0.01 to 50 parts by mass relative to 100 parts by mass of the resin which contains as a main component a structure represented by the general formula(e) (1) and/or (2). Among these, a quinonediazide compound is preferably contained in an amount of 3 to 40 parts by mass. Furthermore, the total amount of a compound(s) selected from sulfonium salts, phosphonium salts, and diazonium salts is preferably 0.05 to 40 parts by mass, more preferably 0.1 to 30 parts by mass. When the amount of the photo acid generator is within this range, a higher sensitivity is achieved. A sensitizer or the like may further be contained depending on need.

The photosensitive resin composition according to the present invention contains a multifunctional acrylate compound.

As used herein, an acrylate compound refers to a compound having an acryloyl group or a methacryloyl group. Examples thereof can include acrylic esters, methacrylic esters, acrylamides, methacryl amides, and the like. As used herein, a multifunctional acrylate compound refers to a compound having two or more acryloyl groups and/or methacryloyl groups.

The photosensitive resin composition according to the present invention is heat-treated after pattern processing. In the photosensitive resin composition used as a positive-working composition, multifunctional acrylate compounds are thermally polymerized among them or react with an alkali-soluble resin, and are crosslinked, thereby enhancing the degree of elongation of the cured film. In the photosensitive resin composition used as a negative-working composition, acrylate compounds are photopolymerized among them by exposure during pattern processing, thereby forming a network structure with an alkali-soluble resin. With monofunctional acrylate compounds, film curing by crosslinking reaction does not progress sufficiently, resulting in a low effect of enhancing degree of elongation, and thus multifunctional acrylates are preferable.

Preferable examples of multifunctional acrylate compounds include the NK Ester Series available from Shin-Nakamura Chemical Co., Ltd.: 1G, 2G, 3G, 4G, 9G, 14G, 23G, BG, HD, NPG, 9PG, 701, BPE-100, BPE-200, BPE-500, BPE-1300, A-200, A-400, A-600, A-HD, A-NPG, APG-200, APG-400, APG-700, A-BPE-4, 701A, TMPT, A-TMPT, A-TMM-3, A-TMM-3L, A-TMMT, A-9300, ATM-4E, ATM-35E, ATM-4P, AD-TMP, AD-TMP-L, and A-DPH; and the like. Additional examples include the Light Ester Series available from Kyoeisha Chemical Co., Ltd.: P-1M, P-2M, EG, 2EG, 3EG, 4EG, 9EG, 14EG, 1.4BG, NP, 1.6HX, 1.9ND, 1.10DC, G-101P, G-201P, DCP-M, BP-2EM, BP-4EM, BP-6EM, and TMP; and the like. Additional examples include the Light Acrylate Series available from Kyoeisha Chemical Co., Ltd.: 3EG-A, 4EG-A, 9EG-A, 14EG-A, TMGA-250, NP-A, MPD-A, 1.6HX-A, BEPG-A, 1.9ND-A, MOD-A, DCP-A, BP-4EA, BP-4PA, BA-134, BP-10EA, HPP-A, TMP-A, TMP-3EO-A, TMP-6EO-3A, PE-3A, PE-4A, and DPE-6A; and the like. Additional examples include the Epoxy Ester Series available from Kyoeisha Chemical Co., Ltd.: 40EM, 70PA, 200PA, 80MFA, 3002M, 3002A, 3000M, and 3000A; and the like. Additional examples include the “ARONIX (registered trademark)” Series available from Toagosei Co., Ltd.: M-203, M-208, M-210, M-211B, M-215, M-220, M-225, M-240, M-243, M-245, M-260, M-270, M-305, M-309, M-310, M-313, M-315, M-320, M-325, M-350, M-360, M-402, M-408, and M-450; and the like. Additional examples include the “KAYARAD (registered trademark)” Series available from Nippon Kayaku Co., Ltd.: R-526, NPGDA, PEG400DA, MANDA, R-167, HX-220, HX-620, R-551, R-712, R-604, R-684, GPO-303, TMPTA, THE-330, TPA-320, TPA-330, PET-30, T-1420(T), and RP-1040, and the like. Additional examples include the “BLEMMER (registered trademark)” Series available from NOF Corporation: GMR-H, GAM, PDE-50, PDE-100, PDE-150, PDE-200, PDE-400, PDE-600, PDE-1000, ADE-200, ADE-400, PDP-400, ADP-200, ADP-400, PDT-650, ADT-250, PDBE-200, PDBE-250, PDBE-450, PDBE-1300, ADBE-200, ADBE-250, and ADBE-450; and the like. Additional examples include MBAA available from MRC Unitec Co., Ltd., and the like. The photosensitive resin composition may contain two or more of these compounds.

Among the aforementioned multifunctional acrylate compounds, acrylate compounds having a molecular weight of 100 to 2000 are preferable. The molecular weight of 100 or more can afford a cured film having a high degree of elongation, and the molecular weight of 2000 or less can afford a resin composition having a suitable alkaline solubility and a high compatibility with an alkali-soluble resin.

The photosensitive resin composition according to the present invention may also contain another alkali-soluble resin in addition to the resin having a structure represented by the general formulae (1) and (2), to the extent that the heat resistance of the cured film obtained by heat treatment is not impaired. Specific examples include; alkali-soluble polybenzoxazole, polybenzoxazole precursor, polyamide, acrylic polymer obtained by copolymerization of acrylic acid, siloxane resin; phenol resins such as novolac resin, resole resin, and polyhydroxystyrene resin; resins in which crosslink groups such as methylol groups, alkoxymethyl groups, or epoxy groups are introduced; copolymers of these resins; and the like. These resins are soluble in an alkaline aqueous solution containing an alkali such as tetramethylammonium hydroxide, choline, triethylamine, dimethylaminopyridine, monoethanolamine, diethylaminoethanol, sodium hydroxide, potassium hydroxide, or sodium carbonate. The addition of any of these alkali-soluble resins makes it possible to impart the characteristics of this alkali-soluble resin while maintaining the adhesiveness and high sensitivity of the heat-resistant resin film. It is preferable that the resin containing a structure represented by the general formulae (1) and (2) account for 30 mass % or more of the resin contained in the photosensitive resin composition according to the present invention.

Furthermore, for the purpose of improving the sensitivity of the photosensitive resin composition, a compound having a phenolic hydroxyl group may be contained if needed, provided that the shrinkage after curing is not reduced.

Examples of the compound having a phenolic hydroxyl group include Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCR-IPZ, BisOCP-IPZ, BisOIPP-CP, Bis26X-IPZ, BisOTBP-CP, TekP-4HBPA (tetrakisP-DO-BPA), TrisP-HAP, TrisP-PA, TrisP-SA, TrisOCR-PA, BisOFP-Z, BisRS-2P, BisPG-26X, BisRS-3P, BisOC-OCHP, BisPC-OCHP, Bis25X-OCHP, Bis26X-OCHP, BisOCHP-OC, Bis236T-OCHP, methylenetris-FR-CR, BisRS-26X, BisRS-OCHP (those listed above are the names of products available from Honshu Chemical Industry Co., Ltd.), BIR-OC, BIP-PC, BIR-PC, BIR-PTBP, BIR-PCHP, BIP-BIOC-F, 4PC, BIR-BIPC-F, and TEP-BIP-A (those listed above are the names of products available from Asahi Organic Chemicals Industry Co., Ltd.).

Among those listed above, a preferred compound having a phenolic hydroxyl group for use in the present invention is, for example, Bis-Z, BisP-EZ, TekP-4HBPA, TrisP-HAP, TrisP-PA, BisOCHP-Z, BisP-MZ, BisP-PZ, BisP-IPZ, BisOCP-IPZ, BisP-CP, BisRS-2P, BisRS-3P, BisP-OCHP, methylenetris-FR-CR, BisRS-26X, BIP-PC, BIR-PC, BIR-PTBP, BIR-BIPC-F, or the like. Among these, a particularly preferred compound having a phenolic hydroxyl group is, for example, Bis-Z, TekP-4HBPA, TrisP-HAP, TrisP-PA, BisRS-2P, BisRS-3P, BIR-PC, BIR-PTBP, or BIR-BIPC-F. Since the compound having a phenolic hydroxyl group is contained, the resulting resin composition does not dissolve in an alkaline developer much before exposure to light but readily dissolves in the alkaline developer upon exposure to light.

The content of a compound having a phenolic hydroxyl group is preferably in the range of 1 to 50 parts by mass, more preferably 3 to 40 parts by mass, relative to 100 parts by mass of the resin which contains as a main component a structure represented by the general formula(e) (1) and/or (2).

The photosensitive resin composition according to the present invention contains a solvent. Examples of the solvent include polar aprotic solvents such as N-methyl-2-pyrrolidone, γ-butyrolactone, N,N-dimethylformamide, N,N-dimethylacetamide, N,N-dimethylformamide, N,N-dimethylisobutyric acid amide, and dimethyl sulfoxide; ethers such as tetrahydrofuran, dioxane, propylene glycol monomethyl ether, diethylene glycol ethyl methyl ether; ketones such as acetone, methyl ethyl ketone, diisobutyl ketone, and diacetone alcohol; esters such as ethyl acetate, propylene glycol monomethyl ether acetate, 3-methoxymethyl propanoate, 3-ethoxyethyl propanoate, ethyl acetate, and ethyl lactate; and aromatic hydrocarbons such as toluene and xylene. Two or more of these may be contained. The content of the solvent is preferably from 100 parts by mass to 1500 parts by mass relative to 100 parts by mass of the resin which contains as a main component a structure represented by the general formula(e) (1) and/or (2), because this content can afford a photosensitive resin composition having a suitable viscosity.

The photosensitive resin composition having a positive-working photosensitivity according to the present invention may contain components other than above-described, and preferably contains as a crosslinking agent a compound having an alkoxymethyl group, a methylol group, or an epoxy group. Since the methylol group and alkoxymethyl group undergo a crosslinking reaction in the temperature region of 100° C. or higher, a crosslink is formed by heat treatment and a heat-resistant resin film having high mechanical characteristics is obtained.

Examples of compounds having an alkoxymethyl group or a methylol group include DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, and HMOM-TPHAP (those listed above are the names of products available from Honshu Chemical Co., Ltd.), NIKALAC (registered trademark) MX-290, NIKALAC MX-280, NIKALAC MX-270, NIKALAC MX-279, NIKALAC MW-100LM and NIKALAC MX-750LM (those listed above are the names of products available from Sanwa Chemical Co., Ltd.). Among these, the addition of HMOM-TPHAP or MW-100LM containing many alkoxymethyl groups is preferable because the crosslinking efficiency is good.

Furthermore, since epoxy groups are thermally crosslinked with polymers at 200° C. or lower and the crosslinking does not cause a dehydration reaction, the film does not shrink much and thus the epoxy groups are effective for achieving mechanical characteristics as well as low-temperature curing and reducing warpage. Examples of the compound having an epoxy group include silicones containing an epoxy group such as bisphenol A epoxy resin, bisphenol F epoxy resin, propylene glycol diglycidyl ether, polypropylene glycol diglycidyl ether, and polymethyl(glycidyloxypropyl) siloxane. However, the present invention is not limited in any way by these examples. Specific examples include EPICLON 850-S, EPICLON HP-4032, EPICLON HP-7200, EPICLON HP-820, EPICLON HP-4700, EPICLON EXA-4710, EPICLON HP-4770, EPICLON EXA-859CRP, EPICLON EXA-1514, EPICLON EXA-4880, EPICLON EXA-4850-150, EPICLON EXA-4850-1000, EPICLON EXA-4816, and EPICLON EXA-4822 (those listed above are the names of products available from Dainippon Ink and Chemicals), RIKARESIN BEO-60E (the name of a product available from New Japan Chemical Co., Ltd.), EP-4003S and EP-40005 (ADEKA CORPORATION).

Two or more of these compounds having an alkoxymethyl group, a methylol group, or an epoxy group may be contained.

The content of the compound having an alkoxymethyl group, a methylol group, or an epoxy group is 10 to 50 parts by mass, preferably 10 to 40 parts by mass, relative to 100 parts by mass of the resin containing as a main component a structure represented by the general formula(e) (1) and/or (2).

The photosensitive resin composition according to the present invention may further contain a silane compound. The addition of a silane compound improves the adhesiveness of the heat-resistant resin film. Specific examples of the silane compound include N-phenyl aminoethyl trimethoxysilane, N-phenyl aminoethyl triethoxysilane, N-phenyl aminopropyl trimethoxysilane, N-phenyl aminopropyl triethoxysilane, N-phenyl aminobutyl trimethoxysilane, N-phenyl aminobutyl triethoxysilane, vinyltrimethoxysilane, vinyltriethoxysilane, vinyltrichlorosilane, vinyl-tris(β-methoxyethoxy)silane, 3-methacryloxypropyl trimethoxysilane, 3-acryloxypropyl trimethoxysilane, p-styryl trimethoxysilane, 3-methacryloxypropylmethyl dimethoxysilane, and 3-methacryloxypropylmethyl diethoxysilane. The content of the silane compound is preferably 0.01 parts by mass to 15 parts by mass relative to 100 parts by mass of the resin which contains as a main component a structure represented by the general formula(e) (1) and/or (2).

Furthermore, for the purpose of improving wettability on a base material, the photosensitive resin composition having a positive photosensitivity according to the present invention may contain, depending on need, a surfactant; an ester such as ethyl lactate or propylene glycol monomethyl ether acetate; an alcohol such as ethanol; a ketone such as cyclohexanone or methyl isobutyl ketone; an ether such as tetrahydrofuran or dioxane, and/or the like. Furthermore, for the purpose of, for example, reducing thermal expansion coefficient, increasing dielectric constant, or reducing dielectric constant, the photosensitive resin composition may contain inorganic particles such as silicon dioxide or titanium dioxide or polyimide powder or the like.

The following describes examples of a method of producing a photosensitive resin composition according to the present invention. Examples include a method by which the components described earlier and other components depending on need are put in a glass flask or a stainless steel vessel and stirred to dissolve with a mechanical stirrer or the like; a method by which the mixture is dissolved ultrasonically; and a method by which the mixture is stirred to dissolve with the use of a planetary mixing defoamer. The viscosity of the positive-working photosensitive resin composition is preferably 1 to 10,000 mPa·s. Furthermore, the photosensitive resin composition may be passed through a filter having a pore size of 0.1 μm to 5 μm for removing impurities.

The following describes a method of forming a pattern of a heat-resistant resin film from the photosensitive resin composition according to the present invention.

The photosensitive resin composition according to the present invention may be made into a pattern of a polyimide through a process of applying the photosensitive resin composition on a support substrate and drying the photosensitive resin composition, a process of exposing the photosensitive resin composition to light, a process of developing the photosensitive resin composition, and a process of heat-treating the photosensitive resin composition.

First, a photosensitive resin composition is applied on a substrate. The substrate is of, but not limited to, a silicon wafer, ceramics, gallium arsenide, metal, glass, metallic oxide dielectric film, silicon nitride, ITO, or the like. The photosensitive resin composition may be applied by spin coating using a spinner, spray application, roll coating, slit die coating, or the like. The photosensitive resin composition is usually applied so that the applied resin composition after drying will have a thickness of 0.1 to 150 μm, although the thickness depends on the method of application and the solid concentration, viscosity, or the like of the positive-working photosensitive resin composition.

Next, the substrate which has the photosensitive resin composition thereon is dried to obtain a photosensitive resin film. The drying is performed preferably at a temperature of 50° C. to 150° C. for 1 minute to several hours with the use of an oven, hot plate, infrared rays, or the like.

Next, the photosensitive resin film is irradiated with actinic rays through a mask in a desired pattern. Examples of the actinic rays used for exposure include ultraviolet rays, visible rays, electron rays, and X rays, and in the present invention, it is preferable to use i-line (365 nm), h-line (405 nm), or g-line (436 nm) of a mercury lamp.

In order to form a pattern from the photosensitive resin film in a positive-working manner, it is only necessary to remove the exposed portion with the use of a developer after exposure. The developer is preferably an aqueous solution of an alkaline compound such as tetramethylammonium, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, or hexamethylenediamine. In some cases, these alkaline aqueous solutions may contain one or more of the following: polar solvents such as N-methyl-2-pyrrolidone, N,N-dimethylformamide, N,N-dimethylacetamide, dimethyl sulfoxide, γ-butyrolactone, and dimethylacrylamide; alcohols such as methanol, ethanol, and isopropanol; esters such as ethyl lactate and propylene glycol monomethyl ether acetate; ketones such as cyclopentanone, cyclohexanone, isobutyl ketone, and methyl isobutyl ketone; and the like. After the development, the photosensitive resin film is usually rinsed with water. In the process of rinsing, the water may contain one or more of the following: alcohols such as ethanol and isopropyl alcohol; esters such as ethyl lactate, propylene glycol monomethyl ether acetate, and 3-methoxymethyl propanoate; and the like.

After the development, the photosensitive resin film is heated at a temperature of 100° C. to 400° C. to become a heat-resistant resin film. This heat treatment is performed preferably for 5 minutes to 5 hours while gradually raising the temperature to a selected temperature or sequentially raising the temperature within a selected temperature range. The photosensitive resin composition according to the present invention can obtain a high degree of elongation even when treated at a low temperature of 250° C. or less, for example, by a method by which heat treatment is performed at 220° C. for 1 hour after a treatment at 100° C. for 30 minutes, a method by which heat treatment is performed at 220° C. for 1 hour after the temperature is raised linearly from room temperature to 220° C. in 1 hour, or another method.

The following describes examples of a method of producing and a method of processing a photosensitive resin composition according to the present invention in using the composition as a photosensitive sheet.

A base material is coated with the photosensitive resin composition produced as above-described, from which an organic solvent is removed to produce a photosensitive sheet.

As a base material to be coated with the photosensitive resin composition, polyethylene terephthalate (PET) or the like can be used. When a PET film as a base material needs to be released and removed from a photosensitive sheet which is used to be adhered to a substrate such as a silicon wafer, it is preferable to use a PET film whose surface is coated with a mold release agent such as a silicone resin, because the PET film can be easily released from the photosensitive sheet.

As the methods for coating a PET film with the photosensitive resin composition, screen printing, spray coaters, bar coaters, blade coaters, die coaters, spin coaters, or the like can be used. Examples of methods for removing an organic solvent include not only heating with an oven or a hot plate but also drying in a vacuum, heating with electromagnetic waves such as infrared rays and microwaves, and the like. In this regard, when the organic solvent is not sufficiently removed, a cured product obtained in the subsequent curing treatment may end up in the uncured state or may have poor thermomechanical characteristics. The thickness of the PET film is not limited to a particular value, but is preferably in the range of 30 to 80 μm from the viewpoint of workability. In addition, the surface of the photosensitive sheet may have a cover film attached thereto in order to protect the surface from dirt and the like in the atmosphere. In addition, when the photosensitive resin composition has a low concentration of solid and hence cannot produce a photosensitive sheet having a desired film thickness, two or more photosensitive sheets from which an organic solvent has been removed may be adhered together.

In adhering the photosensitive sheet produced by the aforementioned method to another substrate, a laminating device such as a roll laminater or a vacuum laminater may be used, or a rubber covered roller may be used to manually adhere the photosensitive sheet to a substrate heated on a hot plate. After being adhered to a substrate, the photosensitive sheet is sufficiently cooled and then the PET film is released therefrom.

Next, in the same manner as the aforementioned method for forming a pattern of a heat-resistant resin film using the photosensitive resin composition, the photosensitive sheet adhered to a substrate is irradiated with actinic rays through a mask having a desired pattern, the exposed parts are removed using a developer, and then a temperature of 100° C. to 400° C. is applied such that the photosensitive sheet is converted to a heat-resistant resin film.

The heat-resistant resin film formed from the photosensitive resin composition according to the present invention may be used in an electronic component of a semiconductor device, a multilayer wiring board, or the like. Specifically, the heat-resistant resin film is suitable for use in the applications of a passivation film of a semiconductor, a surface protective film or an interlayer dielectric film of a semiconductor device, an interlayer dielectric film for high-density multilayer wiring, a surface protective film or an interlayer dielectric film of an inductor device, a dielectric layer or a spacer layer for an organic electroluminescent element, and the like, and the heat-resistant resin film is not limited to these applications but may have a variety of structures.

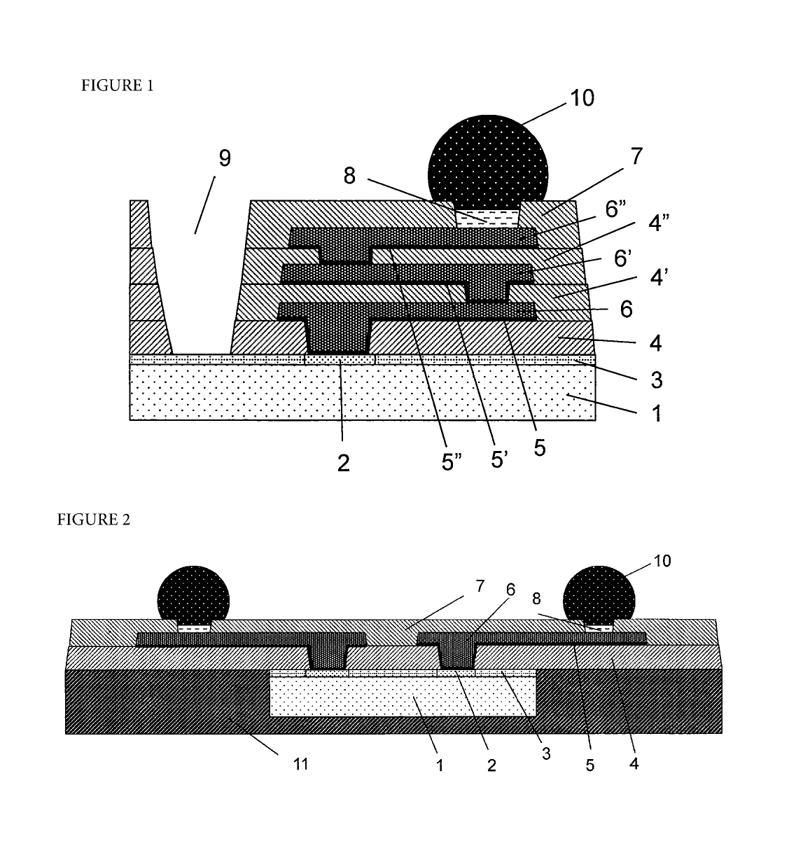

The following describes Application Example 1 of the photosensitive resin composition according to the present invention applied to a semiconductor device having a bump, with reference to the drawings. FIG. 1 is an enlarged cross-sectional view of a pat portion of a semiconductor device having a dielectric film according to the present invention. As illustrated in FIG. 1, a silicon wafer 1 has an Al pad 2 for input/output thereon that has a passivation film 3 thereon, and the passivation film 3 has a via hole. On the passivation film 3, a dielectric film 4 as a pattern made of the photosensitive resin composition according to the present invention is formed, and a metal film 5 (Cr, Ti, or the like) is further formed so as to be connected to the Al pad 2. On this, metal wiring 6 is formed. Repeating the steps of 4 to 6 a plurality of times to form a layer allows a semiconductor device having a high density and a high performance to be produced without expanding the chip area. After this, a barrier metal 8 and a solder bump 10 are formed at the opening of a dielectric film 7.

The following describes Application Example 2 of the photosensitive resin composition according to the present invention applied to a semiconductor device having a bump, with reference to the drawings. FIG. 2 is an enlarged cross-sectional view of a pat portion of a semiconductor device having a dielectric film according to the present invention. In the same manner as in the aforementioned application Example 1, the silicon wafer 1 with the Al pad 2 and the passivation film 3 formed thereon is diced and cut into chips, each of which is then sealed with a resin 11. On this sealing resin 11 and the chip, a dielectric film 4 is formed in the form of a pattern made of the photosensitive resin composition of the present invention, and a metal film 5 (Cr, Ti, or the like) and metal wiring 6 are further formed. After this, a barrier metal 8 and a solder bump 10 are formed at the opening that is in a dielectric film 7 and formed on the sealing resin outside of the chip.

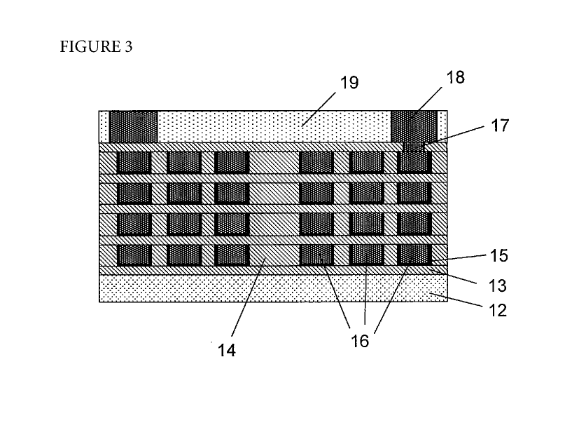

The following describes Application Example 3 of the photosensitive resin composition according to the present invention applied to a coil part of an inductor device, with reference to the drawings. FIG. 3 is a cross-sectional view of a coil part having a dielectric film according to the present invention. As shown in FIG. 3, a substrate 12 is laid with a dielectric film 13 with a patterned dielectric film 14 formed thereon. Ferrite or the like is used for the substrate 12. The photosensitive resin composition according to the present invention may be used for either the dielectric film 13 or the dielectric film 14. In the opening of this pattern, a metal film 15 (Cr, Ti, or the like) is formed, on which metal wiring 16 (Ag, Cu, or the like) is plated. The metal wiring 16 (Ag, Cu, or the like) is formed into a spiral shape. Repeating the steps of 13 to 16 a plurality of times to form a layer can afford a function of a coil. In a final stage, the metal wiring 16 (Ag, Cu, or the like) is connected to an electrode 18 by metal wiring 17 (Ag, Cu, or the like), and sealed with a sealing resin 19.

In a case where the photosensitive resin composition has a soft component introduced thereinto, the wafer does not warp much and thus it is possible to perform light exposure and transport the wafer with high accuracy. This is particularly useful for devices such as those of FIG. 1 and FIG. 3 that have an increased number of layers having a dielectric film and a wiring layer. Furthermore, it is possible to reduce the stress from a sealing resin also during packaging, and hence to provide a highly durable semiconductor device. The photosensitive resin composition formed into the dielectric films 4′, 4″, and 7 in a device such as in FIG. 1 will undergo thick film processing at a scribe line 9, and hence is preferably a photosensitive resin composition that is more transparent, affords a high residual film rate to the unexposed parts, and leaves no residue on the exposed parts.

In addition, the dielectric film 4 is formed over a silicon wafer and a sealing resin in a device such as in FIG. 2. The photosensitive resin composition that has a rigid alicyclic structure introduced therein can afford a film having a high degree of elongation and thus can reduce a stress arising from the thermal expansion of the sealing resin and the torsion of a substrate. In addition, the photosensitive resin composition preferably causes a smaller warpage because such a substrate has a larger area. From these viewpoints, the photosensitive resin composition according to the present invention is useful for devices such as in FIG. 1 and FIG. 2.

### EXAMPLES

The present invention will be described below by way of Examples and the like, but the present invention is not limited by these Examples. It should be noted that resins and photosensitive resin compositions of Examples were produced and evaluated by the following methods.

(1) Measurement of Molecular Weight

The molecular weight of the alkali-soluble resin according to the present invention was measured using a GPC (gel permeation chromatography) device Waters 2690-996 (available from Nihon Waters K.K.) with N-methyl-2-pyrrolidone (hereinafter referred to as “NMP”) as a developing solvent, and the weight-average molecular weight (Mw) was calculated in terms of polystyrene.

(2) Evaluation on Degree of Elongation

Varnish was applied to an 8-inch silicon wafer by a spin-coating method using the coating/developing device ACT-8 (available from Tokyo Electron Limited) such that the varnish would have a film thickness T1 of 11 μm when prebaked later, and then the varnish on the wafer was prebaked at 120° C. for 3 minutes, heated using an inert oven CLH-21CD-S (available from Koyo Thermo Systems Co., Ltd.) at a heating rate of 3.5° C./minute to 220° C. under a nitrogen gas flow at an oxygen concentration of 20 ppm or less, and heat-treated at 220° C. for 1 hour. The heat-treated film was released using a 46 mass % hydrofluoric acid aqueous solution to afford a cured film (heat-resistant resin film). The cured film obtained by this method was cut into 7 cm×1 cm pieces using a single edged knife, which were tensioned at 50 mm/minute using the TENSILON universal testing machine (RTM-100, available from Orientec Corporation). The value of the amount of elongation obtained after this was divided by the sample length to determine a value of interest. This measurement was carried out for 10 samples, and the largest value from among them was regarded as a degree of elongation. The degree of elongation is preferably 30% or more, more preferably 60% or more.

(3) Measurement of Stress

Varnish was applied to a silicon wafer by a spin-coating method using the coating/developing device ACT-8 such that the varnish would have a film thickness of 10 μm when prebaked later at 120° C. for 3 minutes, and then the varnish on the wafer was prebaked, then heated using the inert oven CLH-21CD-S at a heating rate of 3.5° C./minute to 200° C. under a nitrogen gas flow at an oxygen concentration of 20 ppm or less, and heat-treated at 200° C. for 1 hour. Upon reaching the temperature of 50° C. or lower, the silicon wafer was taken out and the cured film was measured using a stress measurement system FLX2908 (available from KLA-Tencor Corporation). The residual stress is preferably 30 MPa or less, more preferably 20 MPa or less.

(4) Preparation of Developed Film A

Varnish was applied to an 8-inch silicon wafer by spin coating and then baked using a hot plate (ACT-8) at 120° C. for 3 minutes to produce a prebaked film having a thickness of 10 μm. This film was exposed to light using an i-line stepper (NIKON NSR i9) at doses in the range of 0 to 1000 mJ/cm² with a step of 10 mJ/cm². After the exposure, the film was developed with a 2.38 mass % tetramethylammonium (TMAH) aqueous solution (ELM-D, available from Mitsubishi Gas Chemical Co., Inc.) for 90 seconds, and then rinsed with pure water to obtain a developed film A having an isolated pattern of 10 μm.

(5) Evaluation on Sensitivity

In regard to the developed film A, the dose (represented as the minimum dose Eth) at which the exposed portion completely dissolved away after the exposure and development was used as a sensitivity. When the Eth is 400 mJ/cm² or less, the sensitivity is determined as high. A sensitivity of 300 mJ/cm² or less is more preferable.

(6) Evaluation on Residual Film Rate

The percentage of the thickness of the developed film with respect to that of the prebaked film is used as a residual film rate (residual film rate=(thickness of developed film)/(thickness of prebaked film)×100)), and a rate of 80% or more was determined as “pass”.

The following are the abbreviations of acid dianhydrides and diamines in the following Examples and Comparative Examples.

PMDA-HH: 1S,2S,4R,5R-cyclohexane tetracarboxylic dianhydride
TDA-100: 3,4-dicarboxy-1,2,3,4-tetrahydro-1-naphthalenesuccinic dianhydride
CBDA: cyclobutanetetracarboxylic dianhydride
6FDA: 4,4′-hexafluoroisopropylidenediphthalic dianhydride
ODPA: 3,3′,4,4′-diphenylethertetracarboxylic dianhydride
SiDA: 1,1,3,3-tetramethyl-1,3-bis(3-aminopropyl) disiloxane
BAHF: 2,2-bis(3-amino-4-hydroxyphenyl) hexafluoropropane
DAE: 4,4′-diaminodiphenyl ether
NMP: N-methyl-2-pyrrolidone
ED-600: JEFFAMINE ED-600 (which is the name of a product available from HUNTSMAN Corporation)
MAP: meta-aminophenol
NA: 5-norbornene-2,3-dicarboxylic anhydride
KBM-403: 3-glycidoxypropyltrimethoxysilane

The following are thermally crosslinking compounds used in Examples and Comparative Examples.

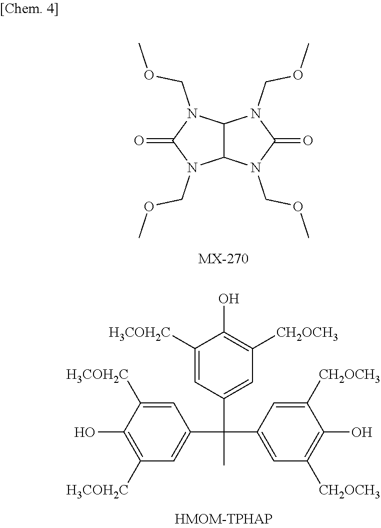

### Synthesis Example 1: Synthesis of Quinonediazide Compound (a)

In a dry nitrogen gas flow, 21.22 g (0.05 mol) of TrisP-PA (name of a product available from HONSHU CHEMICAL INDUSTRY CO., LTD.), 26.86 g (0.10 mol) of 5-naphthoquinonediazide sulfonyl acid chloride, and 13.43 g (0.05 mol) of 4-naphthoquinonediazide sulfonyl acid chloride were dissolved in 50 g of 1,4-dioxane and the temperature was controlled to room temperature. To the obtained mixture, a mixture of 50 g of 1,4-dioxane and 15.18 g of triethylamine was dropped while keeping the temperature inside the system lower than 35° C. After the dropping, the mixture was stirred at 30° C. for 2 hours. The triethylamine salt was filtered out and the filtrate was put in water. After that, the separated precipitate was collected by filtration. The precipitate was dried with a vacuum dryer, to obtain a quinonediazide compound (a) represented by the following formula:

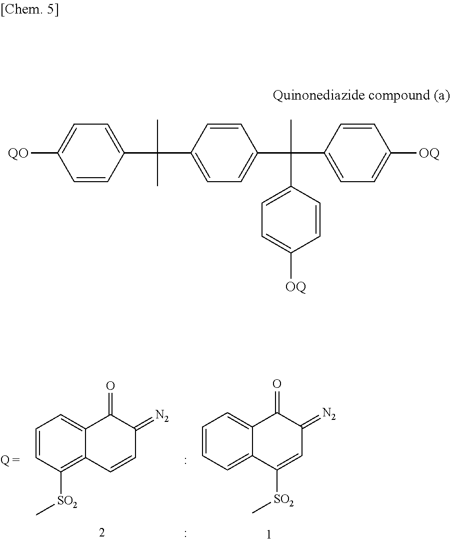

### Synthesis Example 2: Synthesis of Quinonediazide Compound (b)

In a dry nitrogen gas flow, 15.31 g (0.05 mol) of TrisP-HAP (which is the name of a product available from Honshu Chemical Industry Co., Ltd.) and 40.28 g (0.15 mol) of 5-naphthoquinonediazide sulfonyl acid chloride were dissolved in 450 g of 1,4-dioxane, and the temperature was controlled to room temperature. With the use of a mixture of 50 g of 1,4-dioxane and 15.18 g of triethylamine, the same process as in Synthesis Example 2 was performed to obtain a quinonediazide compound (b) represented by the following formula.

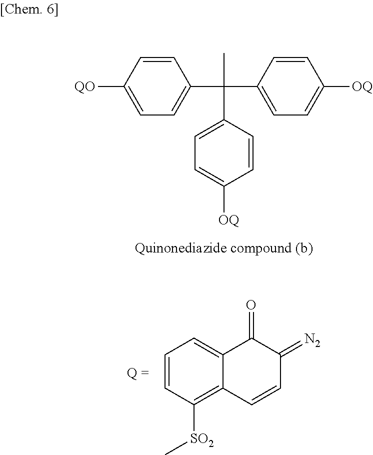

### Synthesis Example 3: Synthesis of Quinonediazide Compound (c)

In a dry nitrogen gas flow, 28.83 g (0.05 mol) of TekP-4HBPA (which is the name of a product available from Honshu Chemical Industry Co., Ltd.) and 13.43 g (0.125 mol) of 5-naphthoquinonediazide sulfonyl acid chloride were dissolved in 450 g of 1,4-dioxane and the temperature was controlled to room temperature. With the use of a mixture of 50 g of 1,4-dioxane and 20.24 g of triethylamine, the same process as in Synthesis Example 2 was performed to obtain a quinonediazide compound (c) represented by the following formula.

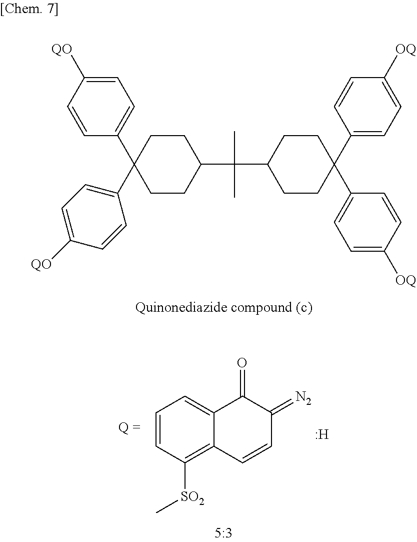

### Synthesis Example 4: Synthesis of Acrylic Resin (d)

To a 500 ml flask, 5 g of 2,2′-azobis(isobutyronitrile), 5 g of t-dodecanthiol, and 150 g of propylene glycol monomethyl ether acetate (hereinafter referred to as PGMEA for short) were introduced. After that, 30 g of methacrylic acid, 35 g of benzyl methacrylate, and 35 g of tricyclo[5.2.1.0^{2,6}]decan-8-yl methacylate were introduced, and stirred at room temperature for a while, the air inside the flask was replaced with nitrogen, and the mixture was then stirred with heat at 70° C. for 5 hours. Next, 15 g of glycidyl methacrylate, 1 g of dimethylbenzylamine, and 0.2 g of p-methoxyphenol were added to the obtained solution, stirred with heat at 90° C. for 4 hours, to obtain a solution of an alkali-soluble acrylic resin (d). The solid concentration of the acrylic resin solution (d) was 43 mass %.

### Synthesis Example 5: Synthesis of Novolac Resin (e)

In a dry nitrogen gas flow, 70.2 g (0.65 mol) of m-cresol, 37.8 g (0.35 mol) of p-cresol, 75.5 g (0.93 mol of formaldehyde) of 37 mass % formaldehyde aqueous solution, 0.63 g (0.005 mol) of oxalic acid dihydrate, and 264 g of methyl isobutyl ketone were introduced, and then immersed in an oil bath, and the reaction liquid was subjected to a polycondensation reaction at reflux for 4 hours. After that, the temperature of the oil bath was raised over 3 hours, the pressure inside the flask was reduced to 40 to 67 hPa, a volatile component was removed, and the resin dissolved in the liquid was cooled to room temperature, to obtain an alkali-soluble novolac resin (e) in the form of a solid polymer. The Mw found by GPC was 3,500. To the obtained novolac resin (e), γ-butyrolactone (GBL) was added to obtain a solution of the novolac resin (e) having a solid concentration of 43 mass %.

### Synthesis Example 6: Synthesis of Polybenzoxazole Precursor (f)

In a dry nitrogen gas flow, 18.3 g (0.05 mol) of BAHF was dissolved in 50 g of NMP and 26.4 g (0.3 mol) of glycidylmethyl ether, and the temperature of the solution was cooled to −15° C. To this solution, a solution obtained by dissolving 14.7 g of diphenyl ether dicarboxylic acid dichloride (0.050 mol, available from Nihon Nohyaku Co., Ltd.) in 25 g of GBL was dropped while keeping the internal temperature to lower than 0° C. After the dropping, the solution was stirred at −15° C. for another 6 hours. After the reaction finished, the solution was poured into 3 L of water containing 10 mass % of methanol and white precipitate was deposited. The deposition was collected by filtration, washed with water three times, and then dried with a vacuum dryer at 50° C. for 72 hours, to obtain an alkali-soluble polybenzoxazole precursor (f). GBL was added to the obtained polybenzoxazole precursor (f) to obtain a solution of polybenzoxazole precursor (f) having a solid concentration of 43 mass %.

### Synthesis Example 7: Synthesis of Polyhydroxystyrene (g)

p-t-butoxystyrene and styrene in a total amount of 20 g at a molar ratio of 3:1 was added to a mixed solution of 500 ml of tetrahydrofuran and 0.01 mol of sec-butyllithium as an initiator and polymerized with stirring for 3 hours. A polymerization termination reaction was caused by adding 0.1 mol of methanol to the reaction liquid. Next, for purification of the polymer, the reaction mixture was poured into methanol and the precipitated polymer was dried, to obtain a white polymer. The polymer was further dissolved in 400 ml of acetone, a small amount of concentrated hydrochloric acid was added at 60° C., and the mixture was stirred for 7 hours, whereafter the mixture was then poured into water, the polymer was precipitated, p-t-butoxystyrene was deprotected to give hydroxystyrene, and the resultant was washed and dried, to obtain a purified copolymer (g) of p-hydroxystyrene and styrene. GBL was added to the obtained copolymer (g) of p-hydroxystyrene and styrene to obtain a solution of the copolymer (g) of p-hydroxystyrene and styrene at a solid concentration of 43 mass %.

### Example 1

In a dry nitrogen gas flow, 5.60 g (0.025 mol) of PMDA-HH and 11.11 g (0.025 mol) of 6FDA were dissolved in 100 g of NMP. To this, 1.09 g (0.010 mol) of 3-aminophenol was added together with 20 g of NMP. Further to this solution, 10.99 g (0.030 mol) of BAHF, 0.50 g (0.003 mol) of DAE, and 6.00 g (0.010 mol) of ED600, and 0.62 g (0.003 mol) of SiDA, together with 20 g of NMP, were added, and allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (A) powder.

21.0 g of the obtained resin (A), 3.0 g of the quinonediazide compound (a) obtained in Synthesis Example 1, 12.0 g the acrylic resin (d) obtained in Synthesis Example 4, 4.0 g of a crosslinking agent MX-270, and 1.0 g of KBM-403 were added to 25 g of GBL to obtain a varnish A of a positive-working photosensitive-working photosensitive resin composition. Table 1 shows the components of the resin (A), and the other resins and photo acid generators of the varnish A. Using the obtained varnish A, degree of elongation, stress, sensitivity, and residual film rate were evaluated as described above. The results of the evaluations are shown in Table 2.

### Example 2

In a dry nitrogen gas flow, 1.12 g (0.005 mol) of PMDA-HH, 11.11 g (0.025 mol) of 6FDA, and 6.20 g (0.020 mol) of ODPA were dissolved in 100 g of NMP. To this, 1.09 g (0.010 mol) of 3-aminophenol was added together with 20 g of NMP. Further to this solution, 10.99 g (0.030 mol) of BAHF, 0.50 g (0.003 mol) of DAE, and 6.00 g (0.010 mol) of ED600, and 0.62 g (0.003 mol) of SiDA, together with 20 g of NMP, were added, and allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (B) powder.

21.0 g of the obtained resin (B), 3.0 g of the quinonediazide compound (b) obtained in Synthesis Example 2, 12.0 g of the novolac resin (e) obtained in Synthesis Example 5, 4.0 g of a crosslinking agent MX-270, and 1.0 g of KBM403 were added to 25 g of GBL to obtain a varnish B of a positive-working photosensitive resin composition. Table 1 shows the components of the resin (B), and the other resins and photo acid generator of the varnish B. Using the obtained varnish B, degree of elongation, stress, sensitivity, and residual film rate were evaluated as described above. The results of the evaluations are shown in Table 2.

### Example 3

In a dry nitrogen gas flow, 4.90 g (0.025 mol) of CBDA and 11.11 g (0.025 mol) of 6FDA were dissolved in 100 g of NMP. To this, 1.09 g (0.010 mol) of 3-aminophenol was added together with 20 g of NMP. Further to this solution, 10.99 g (0.030 mol) of BAHF, 0.50 g (0.003 mol) of DAE, and 6.00 g (0.010 mol) of ED600, and 0.62 g (0.003 mol) of SiDA, together with 20 g of NMP, were added, and allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (C) powder.

21.0 g of the obtained resin (C), 3.0 g of the quinonediazide compound (c) obtained in Synthesis Example 3, 12.0 g of the polybenzoxazole resin (f) obtained in Synthesis Example 6, 4.0 g of a crosslinking agent HMOM-TPHAP, and 1.0 g of KBM-403 were added to 25 g of GBL to obtain a varnish C of a positive-working photosensitive resin composition. Table 1 shows the components of the resin (C), and the other resins and photo acid generator of the varnish C. Using the obtained varnish C, degree of elongation, stress, sensitivity, and residual film rate were evaluated as described above. The results of the evaluations are shown in Table 2.

### Example 4

In a dry nitrogen gas flow, 0.98 g (0.005 mol) of CBDA, 11.11 g (0.025 mol) of 6FDA, and 4.65 g (0.015 mol) of ODPA were dissolved in 100 g of NMP. To this solution, 11.90 g (0.033 mol) of BAHF, 0.50 g (0.003 mol) of DAE, and 7.50 g (0.013 mol) of ED600, and 0.62 g (0.003 mol) of SiDA, together with 20 g of NMP, were added, and allowed to react at 60° C. for 1 hour, and then stirred at 180° C. for 4 hours, whereafter 1.64 g (0.010 mol) of 5-norbornene-2,3-dicarboxylic anhydride was added as a terminal blocking agent, together with 10 g of NMP, and allowed to react at 60° C. for 1 hour. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (D) powder.

21.0 g of the obtained resin (D), 3.0 g of the quinonediazide compound (a) obtained in Synthesis Example 1, 12.0 g of the polyhydroxystyrene resin (g) obtained in Synthesis Example 7, 4.0 g of a crosslinking agent MX-270, and 1.0 g of KBM-403 were added to 25 g of GBL to obtain a varnish D of a positive-working photosensitive resin composition. Table 1 shows the components of the resin (D), and the other resins and photo acid generator of the varnish D. Using the obtained varnish D, degree of elongation, stress, sensitivity, and residual film rate were evaluated as described above. The results of the evaluations are shown in Table 2.

### Example 5

In a dry nitrogen gas flow, 0.98 g (0.005 mol) of CBDA, 11.11 g (0.025 mol) of 6FDA, and 4.50 g (0.015 mol) of TDA-100 were dissolved in 100 g of NMP. To this solution, 11.90 g (0.033 mol) of BAHF, 0.50 g (0.003 mol) of DAE, and 7.50 g (0.013 mol) of ED600, and 0.62 g (0.003 mol) of SiDA, together with 20 g of NMP, were added, and allowed to react at 60° C. for 1 hour, and then stirred at 180° C. for 4 hours, whereafter 1.64 g (0.010 mol) of 5-norbornene-2,3-dicarboxylic anhydride was added as a terminal blocking agent, together with 10 g of NMP, and allowed to react at 60° C. for 1 hour. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (E) powder.

21.0 g of the obtained resin (E), 3.0 g of the quinonediazide compound (a) obtained in Synthesis Example 1, 12.0 g the acrylic resin (d) obtained in Synthesis Example 4, 4.0 g of a crosslinking agent HMOM-TPHAP, and 1.0 g of KBM-403 were added to 25 g of GBL to obtain a varnish E of a positive-working photosensitive resin composition. Table 1 shows the components of the resin (E), and the other resins and photo acid generator of the varnish E. Using the obtained varnish E, degree of elongation, stress, sensitivity, and residual film rate were evaluated as described above. The results of the evaluations are shown in Table 2.

### Comparative Example 1

In a dry nitrogen gas flow, 11.21 g (0.050 mol) of PMDA-HH was dissolved in 100 g of NMP. To this, 1.09 g (0.010 mol) of 3-aminophenol was added together with 20 g of NMP. Further to this solution, 15.57 g (0.043 mol) of BAHF, 1.00 g (0.005 mol) of DAE, and 0.62 g (0.003 mol) of SiDA, together with 20 g of NMP, were added, allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (F) powder.

21.0 g of the obtained resin (F), 3.0 g of the quinonediazide compound (a) obtained in Synthesis Example 1, 12.0 g the acrylic resin (d) obtained in Synthesis Example 4, 4.0 g of a crosslinking agent MX-270, and 1.0 g of KBM-403 were added to 25 g of GBL to obtain a varnish F of a positive-working photosensitive resin composition. Table 1 shows the components of the resin (F), and the other resins and photo acid generator of the varnish F. Using the obtained varnish F, degree of elongation, stress, sensitivity, and residual film rate were evaluated as described above, but the sensitivity evaluation was not performable because all the film dissolved after development. The results of the evaluations are shown in Table 2.

### Comparative Example 2

In a dry nitrogen gas flow, 9.81 g (0.050 mol) of CBDA was dissolved in 100 g of NMP. To this, 1.09 g (0.010 mol) of 3-aminophenol was added together with 20 g of NMP. Further to this solution, 15.57 g (0.043 mol) of BAHF, 1.00 g (0.005 mol) of DAE, and 0.62 g (0.003 mol) of SiDA, together with 20 g of NMP, were added, allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (G) powder.

21.0 g of the obtained resin (G), 3.0 g of the quinonediazide compound (a) obtained in Synthesis Example 1, 12.0 g the acrylic resin (d) obtained in Synthesis Example 4, 4.0 g of a crosslinking agent MX-270, and 1.0 g of KBM-403 were added to 25 g of GBL to obtain a varnish G of a positive-working photosensitive resin composition. Table 1 shows the components of the resin (G), and the other resins and photo acid generator of the varnish G. Using the obtained varnish G, degree of elongation, stress, sensitivity, and residual film rate were evaluated as described above, but the sensitivity evaluation was not performable because all the film dissolved after development. The results of the evaluations are shown in Table 2.

### Comparative Example 3

In a dry nitrogen gas flow, 15.51 g (0.050 mol) of ODPA was dissolved in 100 g of NMP. To this, 1.09 g (0.010 mol) of 3-aminophenol was added together with 20 g of NMP. Further to this solution, 11.90 g (0.033 mol) of BAHF, 1.00 g (0.005 mol) of DAE, and 6.0 g (0.010 mol) of ED600, and 0.62 g (0.003 mol) of SiDA, together with 20 g of NMP, were added, and allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (H) powder.

21.0 g of the obtained resin (H), 3.0 g of the quinonediazide compound (a) obtained in Synthesis Example 1, 12.0 g the acrylic resin (d) obtained in Synthesis Example 4, 4.0 g of a crosslinking agent MX-270, and 1.0 g of KBM-403 were added to 25 g of GBL to obtain a varnish H of a positive-working photosensitive resin composition. Table 1 shows the components of the resin (H), and the other resins and photo acid generator of the varnish H. Using the obtained varnish H, degree of elongation, stress, sensitivity, and residual film rate were evaluated as described above. The results of the evaluations are shown in Table 2.

### Comparative Example 4

In a dry nitrogen gas flow, 7.51 g (0.025 mol) of TDA-100 and 11.11 g (0.025 mol) of 6FDA were dissolved in 100 g of NMP. To this, 1.09 g (0.010 mol) of 3-aminophenol was added together with 20 g of NMP. Further to this solution, 11.90 g (0.033 mol) of BAHF, 1.00 g (0.005 mol) of DAE, and 6.0 g (0.010 mol) of ED600, and 0.62 g (0.003 mol) of SiDA, together with 20 g of NMP, were added, and allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (I) powder.

21.0 g of the obtained resin (I), 3.0 g of the quinonediazide compound (a) obtained in Synthesis Example 1, 12.0 g the acrylic resin (d) obtained in Synthesis Example 4, 4.0 g of a crosslinking agent MX-270, and 1.0 g of KBM-403 were added to 25 g of GBL to obtain a varnish I of a positive-working photosensitive resin composition. Table 1 shows the components of the resin (I), and the other resins and photo acid generator of the varnish I. Using the obtained varnish I, degree of elongation, stress, sensitivity, and residual film rate were evaluated as described above. The results of the evaluations are shown in Table 2.

### Comparative Example 5

In a dry nitrogen gas flow, 22.21 g (0.050 mol) of 6FDA was dissolved in 100 g of NMP. To this, 1.09 g (0.010 mol) of 3-aminophenol was added together with 20 g of NMP. Further to this solution, 11.90 g (0.033 mol) of BAHF, 1.00 g (0.005 mol) of DAE, and 6.0 g (0.010 mol) of ED600, and 0.62 g (0.003 mol) of SiDA, together with 20 g of NMP, were added, and allowed to react at 60° C. for 1 hour, and then stirred at 180° C. for 4 hours. After the stirring was finished, the solution was poured into 2 L of water to obtain white precipitate. The precipitate was collected by filtration, washed with water three times, and then dried with a vacuum dryer at 50° C. for 72 hours, to obtain a cyclized polyimide resin (J) powder.

21.0 g of the obtained resin (J), 3.0 g of the quinonediazide compound (a) obtained in Synthesis Example 1, 12.0 g the acrylic resin (d) obtained in Synthesis Example 4, 4.0 g of a crosslinking agent MX-270, and 1.0 g of KBM-403 were added to 25 g of GBL to obtain a varnish J of a positive-working photosensitive resin composition. Table 1 shows the components of the resin (J), and the other resins and photo acid generator of the varnish J. Using the obtained varnish J, degree of elongation, stress, sensitivity, and residual film rate were evaluated as described above. The results of the evaluations are shown in Table 2.

TABLE 1

| | Molar Ratio | | | | | | | | | | |
|---|---|---|---|---|---|---|---|---|---|---|---|
| | Acid Component | | | | | Diamine Component | | | | | |
| Alkali-Soluble | (Molar Ratio) | | | | | (Molar Ratio) | | | | Terminal | |
| Resin | PMDA-HH | CBDA | TDA100 | ODPA | 6FDA | BAHF | ED600 | DAE | SiDA | MAP | NA |
| A | 50 | | | | 50 | 60 | 20 | 5 | 5 | 20 | |
| B | 10 | | | 40 | 50 | 60 | 20 | 5 | 5 | 20 | |
| C | | 50 | | | 50 | 60 | 20 | 5 | 5 | 20 | |
| D | | 10 | | 30 | 50 | 65 | 25 | 5 | 5 | | 20 |
| E | | 10 | 30 | | 50 | 65 | 25 | 5 | 5 | | 20 |
| F | 100 | | | | | 85 | | 10 | 5 | 20 | |
| G | | 100 | | | | 85 | | 10 | 5 | 20 | |
| H | | | | 100 | | 65 | 20 | 10 | 5 | 20 | |
| I | | | 50 | | 50 | 65 | 20 | 10 | 5 | 20 | |
| J | | | | | 100 | 65 | 20 | 10 | 5 | 20 | |

TABLE 2

| | | | | Evaluation on | | | Evaluation |
|---|---|---|---|---|---|---|---|
| | Alkali- | | | Degree of | | Evaluation on | on Residual |
| | Soluble | Other | Photo Acid | Elongation | Evaluation | Sensitivity | Film Rate |
| | Resin | Resins | Generator | (%) | on Stress (MPa) | (mJ/cm²) | (%) |
| Example 1 | A | (d) | (a) | 70 | 24 | 290 | 82 |
| Example 2 | B | (e) | (b) | 60 | 20 | 280 | 88 |
| Example 3 | C | (f) | (c) | 75 | 24 | 250 | 81 |
| Example 4 | D | (g) | (a) | 60 | 19 | 290 | 85 |
| Example 5 | E | (d) | (a) | 60 | 19 | 250 | 83 |
| Comparative | F | (d) | (a) | 80 | 35 | — | 0 |
| Example 1 | | | | | | | |
| Comparative | G | (d) | (a) | 80 | 34 | — | 0 |
| Example 2 | | | | | | | |
| Comparative | H | (d) | (a) | 20 | 20 | 260 | 80 |
| Example 3 | | | | | | | |
| Comparative | I | (d) | (a) | 15 | 20 | 250 | 85 |
| Example 4 | | | | | | | |
| Comparative | J | (d) | (a) | 20 | 22 | 300 | 96 |
| Example 5 | | | | | | | |

### REFERENCE SIGNS LIST

1: Silicon wafer
2: Al pad
3: Passivation film
4: Dielectric film
5: Metal film (Cr, Ti, or the like)
6: Metal wiring (Al, Cu, or the like)
7: Dielectric film
8: Barrier metal
9: Scribe line
10: Solder bump
11: Sealing resin
12: Substrate
13: Dielectric film
14: Dielectric film
15: Metal film (Cr, Ti, or the like)
16: Metal wiring (Ag, Cu, or the like)
17: Metal wiring (Ag, Cu, or the like)
18: Electrode
19: Sealing resin

1. A photosensitive resin composition comprising a resin having a structure represented by the general formula(e) (1) and/or (2): 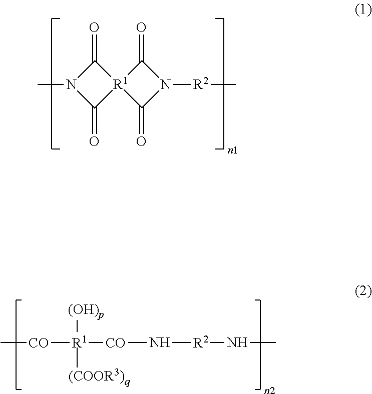
wherein, in the general formulae (1) and (2), R¹ represents a C₄-C₄₀ tetravalent organic group having an alicyclic structure of a monocyclic or fused polycyclic type,
R² represents a C₂₀-C₁₀₀ bivalent organic group having a polyether structure,
R³ represents hydrogen or a C¹-C²⁰ organic group,
n1 and n2 are each in the range of 10 to 100,000, and
p and q are each an integer satisfying 0≦p+q≦6;
wherein the resin contains:
(a) a C₄-C₄₀ organic group as R¹ in the general formulae (1) and (2) at 10 to 80 mol %, the organic group having an alicyclic structure, and
(b) a C₂₀-C₁₀₀ organic group as R₂ in the general formulae (1) and (2) at 10 to 80 mol %, the organic group having a polyether structure.

2. The photosensitive resin composition according to claim 1, wherein R¹ in the resin having a structure represented by the general formula(e) (1) and/or (2) comprises one or more organic groups selected from the general formulae (3) to (6): 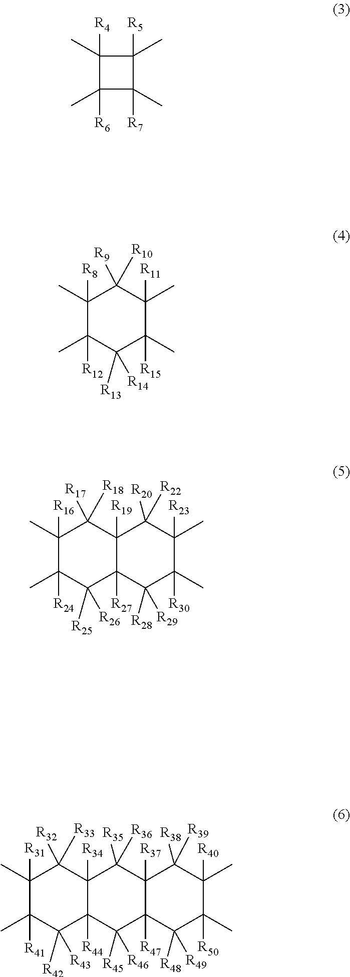
wherein, in the general formulae (3) to (6), R⁴ to R⁵⁰ each independently represent a hydrogen atom, a halogen atom, or a C₁-C₃ monovalent organic group with the proviso that the C₁-C₃ monovalent organic group has a carbon number selected such that R¹ has a carbon number in the range of 4 to 40 wherein a hydrogen atom contained in the C₁-C₃ monovalent organic group is optionally substituted with a halogen atom.

3. The photosensitive resin composition according to claim 1, wherein R² in the resin having a structure represented by the general formula(e) (1) and/or (2) comprises an organic group represented by the general formula (7): 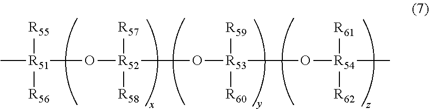
wherein, in the general formula (7), R⁵¹ to R⁵⁴ represent a C₁-C₁₀ tetravalent organic group, and
R⁵⁵ to R⁶² represent a hydrogen atom or a C₁-C₁₀ monovalent organic group.

4. The photosensitive resin composition according to claim 1, wherein the resin having a structure represented by the general formula(e) (1) and/or (2) further comprises an organic group as R¹ at 20 to 90 mol %, the organic group containing a fluorine atom.

5. The photosensitive resin composition according to claim 1, further comprising a photo acid generator.

6. The photosensitive resin composition according to claim 5, further comprising a multifunctional acrylate compound.

7. A photosensitive sheet formed of the photosensitive resin composition according to claim 1.

8. A method for producing a photosensitive sheet, comprising the step of coating a base material with the photosensitive resin composition according to claim 1 and drying the composition.

9. A cured film obtained by curing the photosensitive resin composition according to claim 1.

10. A cured film obtained by curing the photosensitive sheet according to claim 7.

11. An interlayer dielectric film or a semiconductor protective film comprising the cured film according to claim 9.

12. A method for producing a semiconductor electronic component or a semiconductor device, comprising the steps of:
coating a substrate with the photosensitive resin composition according to claim 1;
then carrying out an exposure step and a developing step to form a pattern; and
further heating the resultant to form a relief pattern layer of a cured film.

13. A method for producing a semiconductor electronic component or a semiconductor device, comprising the steps of:
laminating the photosensitive sheet according to claim 7 on a substrate;
then carrying out an exposure step and a developing step to form a pattern thereon; and
further heating the resultant to form a relief pattern layer of a cured film.

14. A semiconductor electronic component or a semiconductor device comprising a relief pattern layer of the cured film according to claim 9.

15. A semiconductor electronic component or a semiconductor device, wherein the cured film according to claim 9 is disposed as an interlayer dielectric film between rewiring layers.

16. A semiconductor electronic component or a semiconductor device, wherein layers each including the rewiring layer and interlayer dielectric film according to claim 15 are disposed one on another two- to ten-fold.

17. A semiconductor electronic component or a semiconductor device, wherein the cured film according to claim 9 is disposed as an interlayer dielectric film covering two or more adjacent substrates made of different kinds of materials.

18. A semiconductor electronic component or a semiconductor device comprising a relief pattern layer of the cured film according to claim 10.
